(19) United States
(12) Patent Application Publication
(10) Pub. No.: US 2010/0261300 A1
(43) Pub. Date: Oct. 14, 2010

(54) METHOD FOR SEPARATING SUBSTRATE FROM SEMICONDUCTOR LAYER

(75) Inventors: PO MIN TU, HSINCHU COUNTY (TW); SHIH CHENG HUANG, HSINCHU COUNTY (TW); YING CHAO YEH, HSINCHU COUNTY (TW); WEN YU LIN, HSINCHU COUNTY (TW); PENG YI WU, HSINCHU COUNTY (TW); CHIH PANG MA, HSINCHU COUNTY (TW); TZU CHIEN HONG, HSINCHU COUNTY (TW); CHIA HUI SHEN, HSINCHU COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: ADVANCED OPTOELECTRONIC TECHNOLOGY INC., HSINCHU COUNTY (TW)

(21) Appl. No.: 12/756,191

(22) Filed: Apr. 8, 2010

(30) Foreign Application Priority Data
Apr. 8, 2009 (TW) 098111612

(51) Int. Cl. H01L 21/306; H01L 21/20; H01L 21/28

(52) U.S. Cl. 438/29; 257/E21.215; 257/E21.09; 257/E21.158

(57) ABSTRACT

A method for separating an epitaxial substrate from a semiconductor layer initially forms a patterned silicon dioxide layer between a substrate and a semiconductor layer, and then separates the substrate from the patterned silicon dioxide layer using two wet etching processes.

### BACKGROUND OF THE INVENTION

1. Field of the Invention

The present invention relates to a method for manufacturing a Group III nitride semiconductor light-emitting device, and relates more particularly to a method for separating a substrate from a semiconductor layer to manufacture a vertical type Group III nitride light-emitting device.

2. Description of the Related Art

In recent years, much LED (light emitting diode)-related research has been devoted to improving the light extraction efficiency of high-power GaN-based light-emitting diodes. As a result, GaN-based light-emitting diodes are widely applied in the high intensity illumination field. For example, light-emitting diodes are used in the backlight modules for is displays in place of cold cathode fluorescent lamps or light bulbs.

Many methods have been developed to improve the light extraction efficiency of LEDs. For example, the light extraction efficiency can be improved by using an omnidirectional reflective cup, roughening light-emitting surfaces, or using flip-chip technology to package LEDs. For every 10-degree increase in the temperature of an LED, the light efficiency decreases 5%. Because a sapphire substrate has poor thermal and electrical conductivity, the heat from an LED using such a substrate cannot be dissipated quickly. To solve the poor heat dissipation issue, a method using a laser to remove the sapphire substrate to obtain a vertical type LED has been developed.

The laser lift off technology utilizes a laser emitting high power light on the interface between the sapphire substrate and the GaN layer. The GaN decomposes into molten GaN and gaseous nitrogen due to high temperature. However, the laser lift off technology has many drawbacks such as damage to a portion of structure caused by local high temperature generated due to non-uniform high temperature distribution over the GaN layer; and an extra removal process is required to remove remnant gallium on the GaN layer.

FIGS. 1A and 1B are cross-sectional views showing a method for separating a substrate disclosed in U.S. Pat. No. 6,071,795. As shown in FIG. 1A, a separating layer 104 and a silicon nitride layer 106 are sequentially formed on a sapphire substrate 102. Next, an adhesive layer 108 is coated on a surface of the silicon nitride layer 106. Thereafter, a silicon substrate 110 is bonded to the layered structure formed on the sapphire substrate 102 based on the adhesive characteristics of the adhesive layer 108. Next, laser beams 112 are introduced onto the separating layer 104 through the surface of the sapphire substrate 102 to decompose the is separating layer 104. Finally, the remnant material on the silicon nitride layer 106 is removed so as to obtain a combination of the silicon substrate 110 and the silicon nitride layer 106. As shown in FIG. 1B, due to the dielectric adhesive layer 108 disposed between the silicon substrate 110 and the silicon nitride layer 106, the combination cannot be a base structure for formation of a vertical type light-emitting device. Moreover, if the adhesive layer 108 is improperly coated, or its material is not suitable, poor adhesion may occur, or defects may be generated in the silicon nitride layer 106.

FIG. 2 is a cross-sectional view showing a method for separating a substrate disclosed in U.S. Pat. No. 6,740,604. The method is similar to that shown in FIGS. 1A and 1B. Laser beams are radiated onto the interface between the first semiconductor layer 202 and the second semiconductor layer 204 so as to decompose the second semiconductor layer 204 at the interface, and the first semiconductor layer 202 can then be separated from the second semiconductor layer 204. The second semiconductor layer 204 can be a film layer formed on a substrate, namely the first semiconductor layer 202. The film layer is then separated from the substrate.

FIG. 3 is a cross-sectional view showing a method for separating a substrate disclosed in U.S. Pat. No. 6,746,889. A plurality of epitaxial layers are grown on a substrate 302, including a first type semiconductor region 304, a light-emitting PN junction region 306 and a second type semiconductor region 308. A plurality of grooves 312 can be formed on the second type semiconductor region 308 by cutting to obtain a plurality of separated light emitting dies 310. A sub-mount 314 is then bonded to the second type semiconductor region 308. Laser beams 316 are radiated through the surface of the substrate 302 to separate the substrate 302 from the first type semiconductor region 304. The separated light emitting dies 310 can be retrieved from the sub-mount 314 for packaging. After the plurality of epitaxial layers are cut, the plurality of light emitting dies 310 may jostle each other while the sub-mount 314 is being bonded. As a result, the light emitting dies 310 may be cracked.

is FIG. 4 is a cross-sectional view showing a method for separating a substrate disclosed in U.S. Pat. No. 6,617,261. A gallium nitride layer 404 is first formed on a sapphire substrate 402. A plurality of grooves 408 are then formed on the gallium nitride layer 404 using an etching process. Next, a silicon substrate 406 is bonded to a surface of the gallium nitride layer 404 having a plurality of grooves 408. Thereafter, an eximer laser radiates beams 410 on the sapphire substrate 402. The laser beams 410 penetrate the transparent sapphire substrate 402, reaching and decomposing the gallium nitride layer 404 so that a silicon substrate 406 having a gallium nitride layer 404 can be obtained. However, the residues of gallium located where the gallium nitride layer 404 decomposes have to be removed using hydrochloric acid, and the separated surface needs to be restored for subsequent epitaxial processes.

FIGS. 5A to 5C are cross-sectional views showing a method for laterally growing nitride semiconductor disclosed in U.S. Pat. No. 6,627,974. The method fabricates a predetermined structure based on the incompatibility between two different crystal systems during an epitaxial process. Referring to FIG. 5A, a first Group III-V nitride layer 504 is initially formed on a sapphire substrate 502, and a patterned silicon dioxide layer 506 is then formed on the first Group III-V nitride layer 504, wherein the patterned silicon dioxide layer 506 includes a plurality of openings 508. Referring to FIG. 5B, a second Group III-V nitride layer 510 is slowly grown from the openings 508 in the patterned silicon dioxide layer 506, forming structures each having a T configuration. Because the silicon dioxide layer 506 belongs to a polycrystal system, the Group III-V nitride layer belonging to a single crystal system cannot be directly formed on the surface of the silicon dioxide layer 506. Therefore, an epitaxially lateral overgrowth (ELOG) phenomenon occurs such that when Group III-V nitride material and silicon dioxide material are continuously formed during the epitaxial process, cavities 514 consequently emerge. Referring back to FIG. 5B, the second Group III-V nitride layer 510 grows upward from the is first Group III-V nitride layer 504 through the openings 508 in the patterned silicon dioxide layer 506 and beyond the surface of the silicon dioxide layer 506, and then laterally grows until it almost completely covers the silicon dioxide layer 506. Consequently, the second Group III-V nitride layer 510 may include a plurality of arrayed structures with T configurations when viewed in one cross section, and may have a discontinuous top surface (not shown) when viewed from above. Referring to FIG. 5C, a third Group III-V nitride layer 512 is next formed on the second Group III-V nitride layer 510. In this method, the sapphire substrate 502 needs to be processed in epitaxial equipment twice, resulting in a low production yield. In addition, the epitaxially lateral growth has to be stopped before two adjacent structures reach each other, and such process control is difficult and unstable.

FIGS. 6A and 6B are cross-sectional views showing a method disclosed in a paper titled “The Fabrication of Vertical Light-Emitting Diodes Using Chemical Lift-Off Process,” IEEE Photonics Technology Letters, Vol. 20, No. 3, Feb. 1, 2008. The method forms a chromium nitride layer 604 on a sapphire substrate 602 as a buffer layer. Next, a gallium nitride layer 616 is formed on the chromium nitride layer 604. Finally, the chromium nitride layer 604 is removed from the sapphire substrate 602 by a wet etching process. As shown in FIG. 6A, a chromium nitride layer 604 is initially formed on a sapphire substrate 602. Next, a gallium nitride layer 616 is formed on the chromium nitride layer 604. The gallium nitride layer 616 may comprise, in sequence, an n-type gallium nitride layer 606, an active layer 608, a p-type gallium nitride layer 610, and a p-type contact layer 612. Thereafter, a metal substrate 614 is formed on the gallium nitride layer 616. As shown in FIG. 6B, using the chromium nitride layer 604 as a sacrificial layer, the chromium layer 604 is removed from the sapphire substrate 602 by a wet etching process. Although a wet etching process can be directly applied to separate the sapphire substrate 602 from the chromium nitride layer 604, due to the poor lattice match between the chromium nitride layer 604 and the gallium nitride layer 616, the gallium nitride layer 616 directly formed on the chromium nitride layer is 604 may result in poor epitaxial quality and adversely affect light extraction efficiency.

Thus, the vertical light-emitting diodes of the present invention resolve the above drawbacks so as to have better epitaxial quality, and due to roughened surfaces, the light output of the vertical light-emitting diodes increases.

### SUMMARY OF THE INVENTION

According to the discussion in the Description of the Related Art and to meet the requirements of industry, the present invention provides a method for separating a substrate and a semiconductor layer. The method comprises the steps of: providing a temporary substrate; forming a patterned silicon dioxide layer on the temporary substrate; forming a semiconductor layer on the patterned silicon dioxide layer; performing a first etching process upon the patterned silicon dioxide layer; and performing a second etching process upon an interface between the temporary substrate and the semiconductor layer to remove from the temporary substrate.

The present invention further provides a method for separating a substrate and a semiconductor layer, which comprises the steps of: providing a temporary substrate; forming a patterned silicon dioxide layer including a plurality of cavities on the temporary substrate; forming a cavity filling layer on the patterned silicon dioxide layer; forming a semiconductor layer on the cavity filling layer; performing a first etching process upon the patterned silicon dioxide layer; and performing a second etching process upon the cavity filling layer to remove from the temporary substrate.

The first etching process of one embodiment of the present invention is a wet etching process, which is performed using buffered oxide etch (BOE) solution to etch the patterned silicon dioxide layer.

The second etching process of one embodiment of the present invention is a wet etching process, which is performed using potassium hydroxide solution, sulfuric acid solution, or phosphoric acid solution to is etch the interface between the temporary substrate and the semiconductor layer.

The cavity filling layer of one embodiment of the present invention comprises Group III-V nitride material.

The method further comprises the steps of: forming a reflective metal layer on the semiconductor layer; and forming an electrically conductive material layer on the reflective metal layer according to one embodiment of the present invention.

The semiconductor layer comprises an n-type conductive layer, a luminescent layer, a p-type conductive layer, and an electron blocking layer disposed between the luminescent layer and the p-type conductive layer according to one embodiment of the present invention.

The patterned silicon dioxide layer, including a plurality of cavities, is a continuous layer or a partially continuous layer, wherein the cavity may comprise a round cylindrical pattern, a polygonal pattern or an elongated pattern according to one embodiment of the present invention.

The patterned silicon dioxide layer has a thickness in a range of from 0.05 to 2 micrometers, and has a width in a range of from 0.1 to 10 micrometers according to one embodiment of the present invention.

To better understand the above-described objectives, characteristics and advantages of the present invention, embodiments, with reference to the drawings, are provided for detailed explanations.

### BRIEF DESCRIPTION OF THE DRAWINGS

The invention will be described according to the appended drawings in which:

FIGS. 1A and 1B are cross-sectional views showing a method for separating a substrate disclosed in U.S. Pat. No. 6,071,795;

FIG. 2 is a cross-sectional view showing a method for separating a substrate disclosed in U.S. Pat. No. 6,740,604;

is FIG. 3 is a cross-sectional view showing a method for separating a substrate disclosed in U.S. Pat. No. 6,746,889;

FIG. 4 is a cross-sectional view showing a method for separating a substrate disclosed in U.S. Pat. No. 6,617,261;

FIGS. 5A to 5C are cross-sectional views showing a method for laterally growing nitride semiconductor disclosed in U.S. Pat. No. 6,627,974;

FIGS. 6A and 6B are cross-sectional views showing a method disclosed in a paper titled “The Fabrication of Vertical Light-Emitting Diodes Using Chemical Lift-Off Process,” IEEE Photonics Technology Letters, Vol. 20, No. 3, Feb. 1, 2008;

FIG. 7 is a flow chart showing the steps of a method for separating a substrate from a semiconductor layer according to one embodiment of the present invention;

FIGS. 8A to 8I are cross-sectional views showing the steps of a method for separating a substrate from a semiconductor layer according to one embodiment of the present invention; and

FIGS. 9A to 9D are top views showing the different cavity patterns formed on a silicon dioxide layer according to alternative embodiments of the present invention.

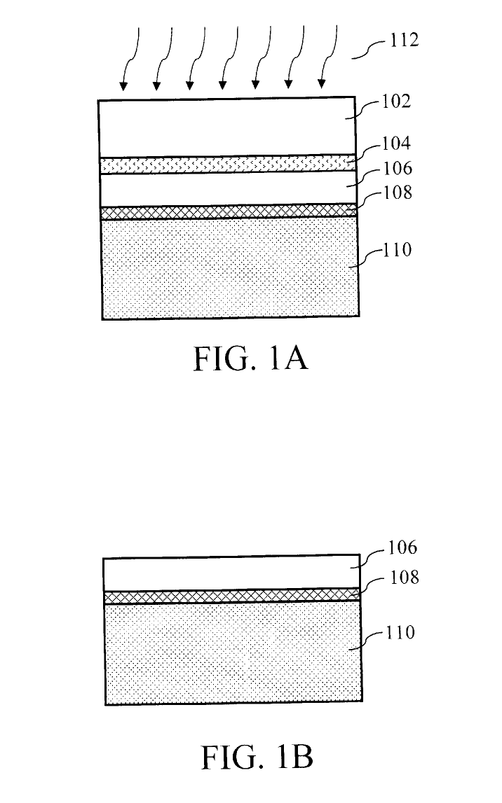

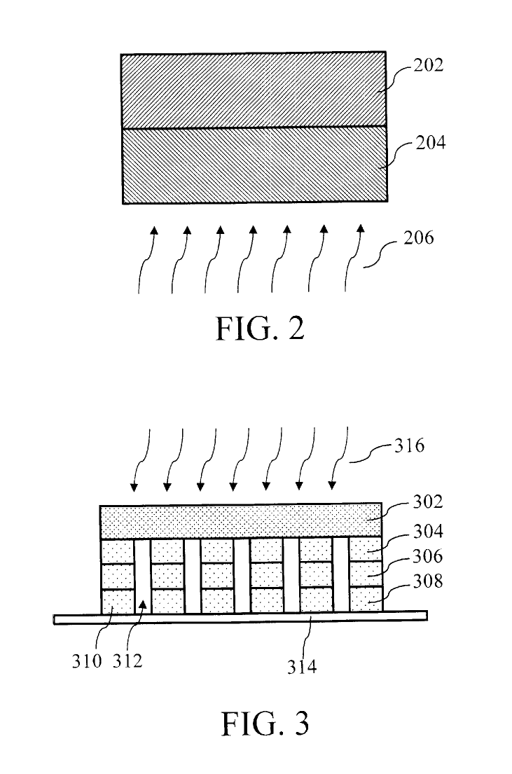

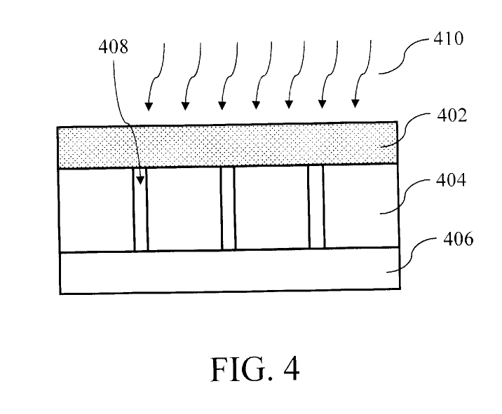

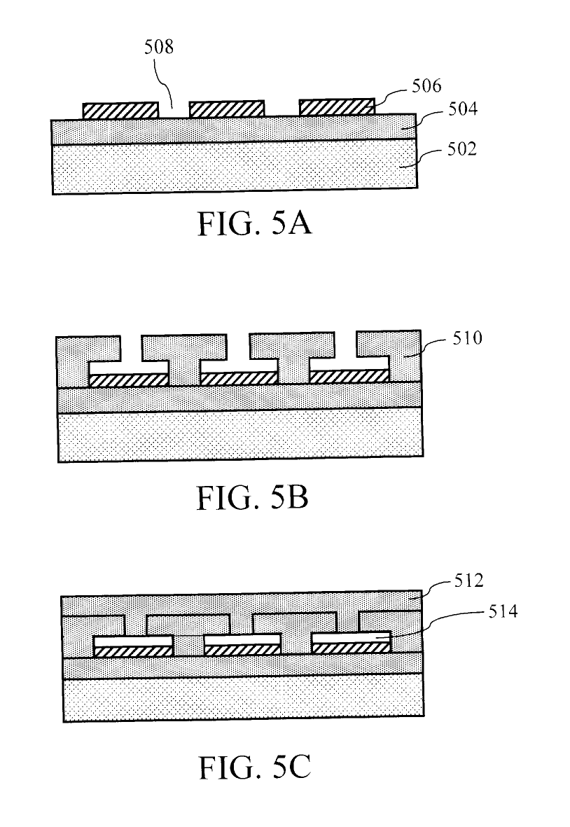

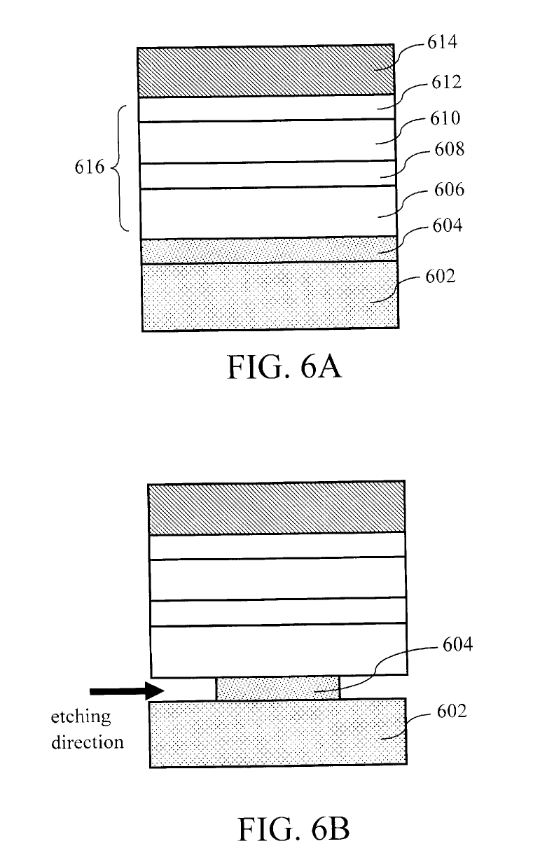

### DETAILED DESCRIPTION OF THE INVENTION

The present invention exemplarily demonstrates a method for separating a substrate and a semiconductor layer. In order to thoroughly understand the present invention, detailed descriptions of method steps and components are provided below. To avoid unnecessary limitations to the present invention, the implementations of the present invention are not is limited to the specific details that are familiar to persons in the art related to optoelectronic semiconductor manufacturing processes. On the other hand, components or method steps that are well known are not described in detail. A preferred embodiment of the present invention is described in detail below. However, in addition to the preferred detailed description, other embodiments can be broadly employed, and the scope of the present invention is not limited by any of the embodiments, but should be defined in accordance with the following claims and their equivalents.

One aspect of the present invention is to provide a simple method for separating a substrate and a semiconductor layer, and to obtain a Group III nitride semiconductor light-emitting device with high quality epitaxial growth.

Another aspect of the present invention is to provide a simple vertical light-emitting device that has low manufacturing cost.

Another aspect of the present invention is to improve the light extraction efficiency of a vertical light-emitting device.

To achieve the above aspects, one embodiment of the present invention provides a method for separating a substrate and a semiconductor layer, which comprises the steps of: providing a temporary substrate; forming a patterned silicon dioxide layer on the temporary substrate; forming a semiconductor layer on the patterned silicon dioxide layer; performing a first etching process upon the patterned silicon dioxide layer; and performing a second etching process upon an interface between the temporary substrate and the semiconductor layer to remove from the temporary substrate.

Another embodiment of the present invention provides a method for separating a substrate and a semiconductor layer, which comprises the steps of: providing a temporary substrate; forming a patterned silicon dioxide layer including a plurality of cavities on the temporary substrate; forming a cavity filling layer on the patterned silicon dioxide layer; forming a semiconductor layer on the cavity filling layer; performing a first etching process upon the patterned silicon dioxide layer; and performing a second etching process upon the cavity filling layer to remove from the temporary substrate.

The first etching process of one embodiment of the present invention is a wet etching process, which is performed using BOE (buffered oxide etch) solution to etch the patterned silicon dioxide layer.

The second etching process of one embodiment of the present invention is a wet etching process, which is performed using potassium hydroxide solution, sulfuric acid solution, or phosphoric acid solution to etch the interface between the temporary substrate and the semiconductor layer.

The cavity filling layer of one embodiment of the present invention comprises Group III-V nitride material.

The method further comprises the steps of: forming a reflective metal layer on the semiconductor layer; and forming an electrically conductive material layer on the reflective metal layer according to one embodiment of the present invention.

The semiconductor layer comprises an n-type conductive layer, a luminescent layer, a p-type conductive layer, and an electron blocking layer disposed between the luminescent layer and the p-type conductive layer according to one embodiment of the present invention.

In one embodiment, the luminescent layer includes a single hetero-structure, a double hetero-structure, a single quantum well layer, or a multiple quantum well layer.

In one embodiment, the semiconductor layer includes AlₓIn_{y}Ga_{l-x-y}N layer where 0≦x≦1, 0≦y≦1.

In one embodiment, the reflective metal layer includes silver or is aluminum silver alloy; the electrically conductive material layer includes diamond-like material, copper, copper tungsten alloy or nickel.

In one embodiment, the temporary substrate is a sapphire (Al₂O₃) substrate, a silicon carbide (SiC) substrate, a silicon substrate, a zinc oxide (ZnO) substrate, a magnesium oxide (MgO) substrate, or a gallium arsenide (GaAs) substrate.

In one embodiment, the patterned silicon dioxide layer, including a plurality of cavities, can be a continuous layer or a partially continuous layer, wherein the cavity may comprise a round cylindrical pattern, a polygonal pattern or an elongated pattern according to one embodiment of the present invention.

In one embodiment, the patterned silicon dioxide layer has a thickness in a range of from 0.05 to 2 micrometers, and has a width in a range of from 0.1 to 10 micrometers.

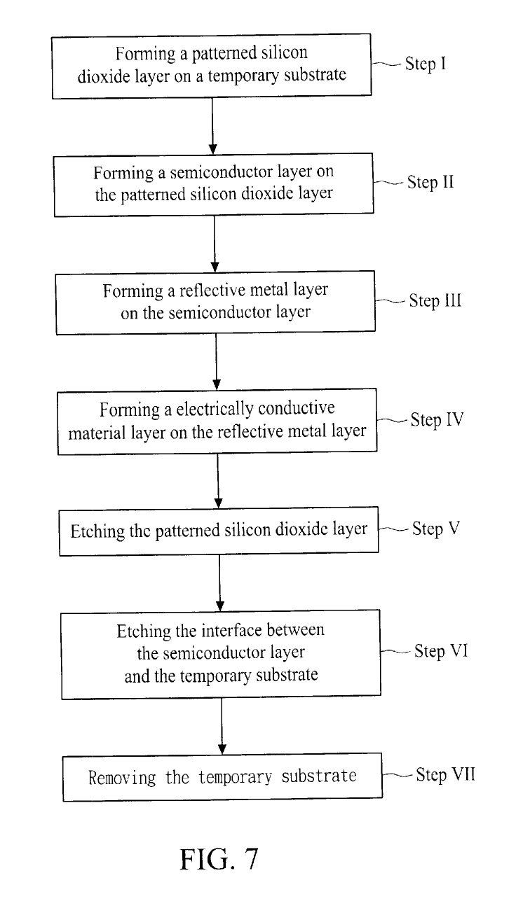

FIG. 7 is a flow chart showing the steps of a method for separating a substrate from a semiconductor layer according to one embodiment of the present invention. In Step I, a patterned silicon dioxide layer is formed on a temporary substrate. The silicon dioxide layer can be a thin film formed on a temporary substrate using a chemical vapor deposition process or a low temperature sputtering process. Using a low temperature process to form the thin silicon dioxide layer can reduce the damage to the device, and can also cause the silicon dioxide layer to be stable. The above-mentioned low temperature can range from 100 degrees to 300 degrees Celsius. Preferably, the low temperature can be 150 degree Celsius. Next, a photoresist film is formed on the surface of the silicon dioxide layer, and is then patterned using photolithography so as to expose portions of the silicon dioxide for etching. The photoresist can be selectively a positive resist or a negative resist. Finally, performing a wet etching or dry etching process, or using an inductively coupled plasma etcher, the silicon dioxide is etched to obtain a patterned silicon dioxide layer.

In Step II, a semiconductor layer is formed on the patterned silicon dioxide layer. To improve the epitaxial quality of the semiconductor layer, a Group III nitride buffer layer is formed on the patterned silicon dioxide layer. Because the silicon dioxide layer belongs to the polycrystal system, the Group III nitride buffer layer belonging to the single crystal system cannot be directly epitaxially formed on the surface of a layer of the polycrystal system. If the Group III nitride buffer layer is directly epitaxially formed on a layer of the polycrystal system, an epitaxially lateral overgrowth phenomenon may occur. During an epitaxial process, discontinuous cavities may appear between the Group III nitride buffer layer and the silicon dioxide layer. The Group III nitride buffer layer is initially formed in openings in the patterned silicon dioxide layer, growing beyond the surface of the silicon dioxide layer, laterally growing along the surface of the silicon dioxide layer, and finally joining together to form a planar buffer layer. Thereafter, a semiconductor layer is formed on the Group III nitride buffer layer. The light-emitting semiconductor layer can be formed on the Group III nitride buffer layer using a metal organic chemical vapor deposition process or a molecular beam epitaxy process. The semiconductor layer may comprise an n-type conductive layer, a luminescent layer, an electron blocking layer, and a p-type conductive layer.

In Step III, a reflective metal layer is formed on the semiconductor layer. The thin metal layer can be formed on the semiconductor layer using an evaporation process or a sputtering process. The reflective metal layer is configured to reflect light from the semiconductor layer so as to increase light output.

In Step IV, an electrically conductive material layer is formed on the reflective metal layer, or an electrically conductive material layer is bonded to the reflective metal layer. The electrically conductive material layer can accelerate the dissipation of the heat from the semiconductor layer and improve the electrical conductivity.

In Step V, the silicon dioxide layer is etched. The silicon dioxide layer can be wet etched. The chemical solution that can react with oxide is selected and is adjusted to a suitable concentration. The silicon dioxide layer is immersed in the chemical solution. The chemical solution reacts with the silicon dioxide layer so as to remove the silicon dioxide layer. After the silicon dioxide layer is removed, the pillar-like Group III nitride buffer layer and the temporary substrate attached thereto are left.

In Steps VI and VII, the interface between the semiconductor layer and the temporary substrate is etched to remove the temporary substrate. The chemical solution for the secondary etching process is one that can react with Group III nitride material. When the chemical solution permeates into the interface between the Group III nitride layer and the temporary substrate, the Group III nitride layer decomposes so that it can be separated from the temporary substrate. The surface eroded by the chemical solution is roughened so as to increase light output.

The above-mentioned forming steps are explained by the following figures each showing the corresponding structure and the descriptions describing the corresponding figure.

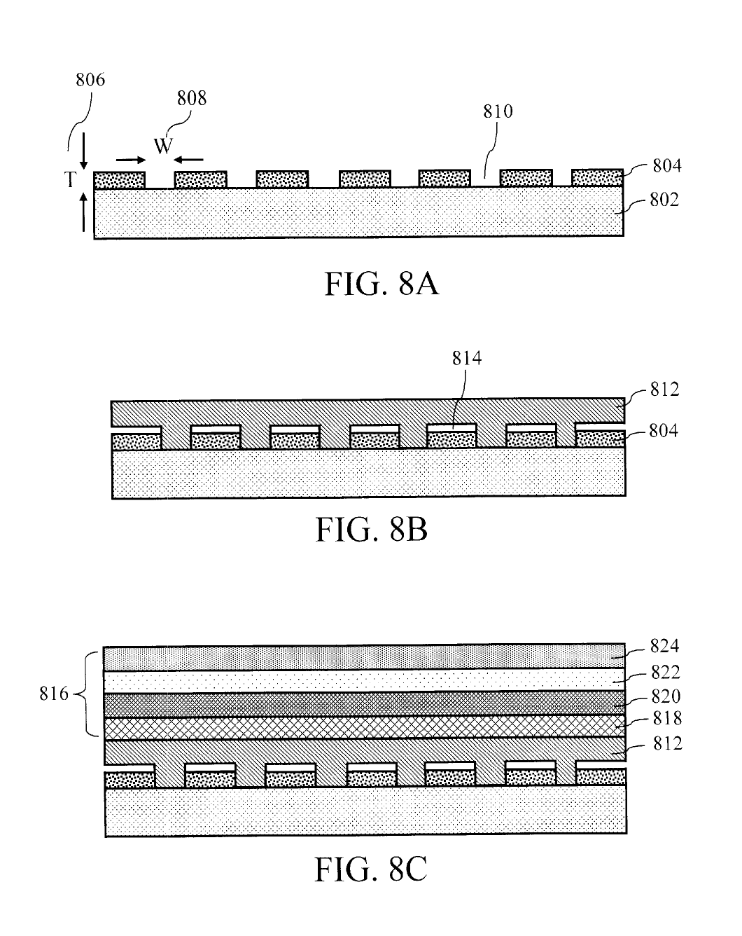

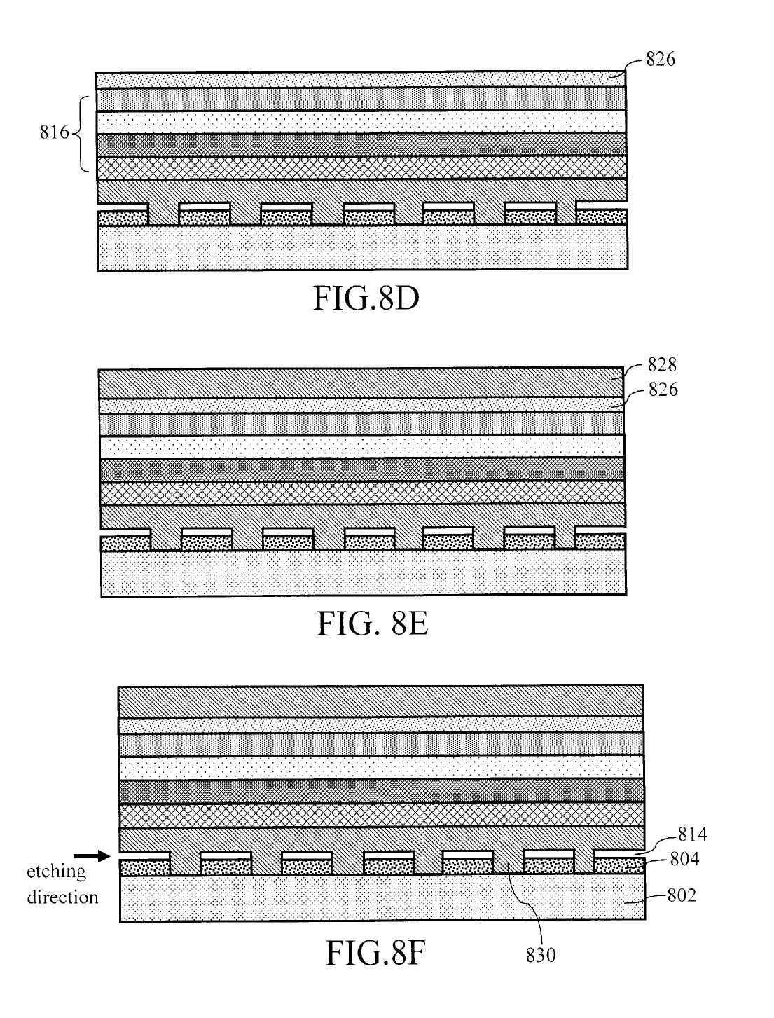

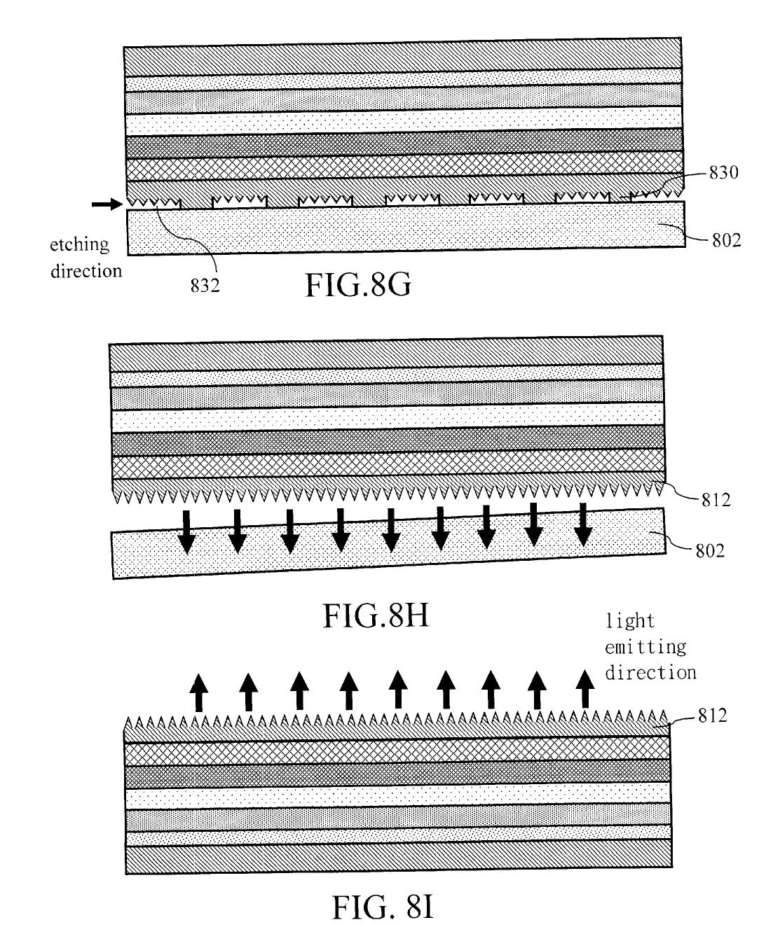

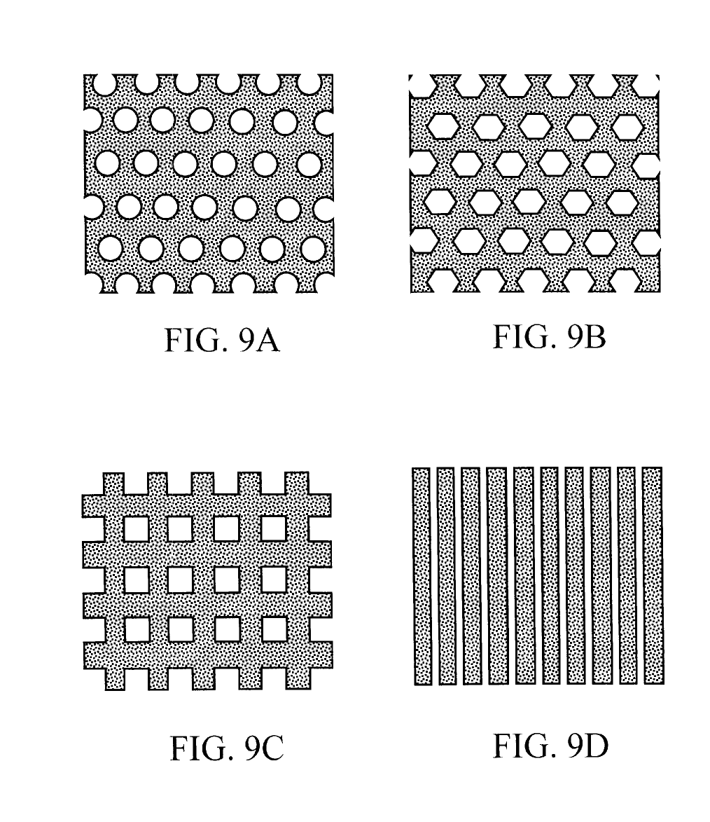

Referring to FIG. 8A, a temporary substrate 802 is provided. A patterned silicon dioxide layer 804 is formed on a temporary substrate 802. The temporary substrate 802 can be a sapphire (Al₂O₃) substrate, a silicon carbide (SiC) substrate, a silicon substrate, a zinc oxide (ZnO) substrate, a magnesium oxide (MgO) substrate, or a gallium arsenide (GaAs) substrate. The silicon dioxide is deposited on a temporary substrate 802 to form a thin layer 804 using a chemical vapor deposition process or a low temperature sputtering process. Using a low temperature process to form the thin layer 804 can reduce the damage to the device, and can also cause the silicon dioxide layer 804 to be stable. Next, a photoresist film is formed on the surface of the silicon dioxide layer 804 and is then patterned using is photolithography so as to expose portions of the silicon dioxide for etching. Finally, performing a wet etching or dry etching process, or using an inductively coupled plasma etcher, the silicon dioxide is etched to obtain a patterned silicon dioxide layer 804. The patterned silicon dioxide layer 804 may include a continuous layer or a partially continuous layer. FIGS. 9A to 9D are top views showing the different cavity patterns formed on a silicon dioxide layer according to alternative embodiments of the present invention. FIG. 9A demonstrates a plurality of round cylindrical cavity patterns; FIG. 9B demonstrates a plurality of hexagonal cavity patterns; FIG. 9C demonstrates a plurality of tetragonal cavity patterns; and FIG. 9D demonstrates a plurality of elongated cavity patterns. In addition, the present invention may include patterns with shapes other than the demonstrated patterns. The patterned silicon dioxide layers 804 in FIGS. 9A to 9C are continuous layers; however, the patterned silicon dioxide layers 804 in FIG. 9D are partially continuous layers. Referring back to FIG. 8A, the patterned silicon dioxide layers 804 may preferably have a thickness (T) 806 of from 0.05 to 2.0 micrometers, and may preferably have a width (W) 808 of from 0.1 to 10 micrometers.

Referring to FIG. 8B, to improve the epitaxial quality of the semiconductor layer, a Group III nitride buffer layer 812 is formed on the patterned silicon dioxide layer 804. Because the silicon dioxide layer belongs to the polycrystal system, the Group III nitride buffer layer 812 belonging to the single crystal system cannot be directly epitaxially formed on the surface of a layer of the polycrystal system due to the poor lattice match. If the Group III nitride buffer layer 812 is directly epitaxially formed on a layer of the polycrystal system, an epitaxially lateral overgrowth phenomenon may occur. During an epitaxial process, discontinuous cavities 814 may appear between the Group III nitride buffer layer 812 and the silicon dioxide layer 804. Utilizing the above-mentioned phenomenon, the Group III nitride buffer layer 812 is initially formed in openings 810, growing beyond the surface of the silicon dioxide layer 804, laterally growing along the surface of the silicon dioxide layer 804, and finally joining together to form a planar buffer layer. Consequently, a plurality of cavities 814 are formed between the Group III nitride buffer layer 812 and the silicon dioxide layer 804. The cavities 814 cause the silicon dioxide layer 804 and the Group III nitride buffer layer 812 to be discontinuous so that etching surfaces can be increased, accelerating the removal of the silicon dioxide layer 804. The Group III nitride buffer layer 812 can be Al_{y}IN_{y}Ga_{l-x-y}N layer where 0≦x≦1, 0≦y≦1.

Referring to FIG. 8C, a semiconductor layer 816 is formed on the Group III nitride buffer layer 812. The semiconductor layer 816 may comprise an n-type conductive layer 818, a luminescent layer 820, an electron blocking layer 822, and a p-type conductive layer 824. The semiconductor layer 816 can be formed on the Group III nitride buffer layer 812 using a metal organic chemical vapor deposition process or a molecular beam epitaxy process. Group IV atoms are initially implanted to form an n-type conductive layer 818 on the Group III nitride buffer layer 812. In the present embodiment, the group IV atom can be a silicon atom. The silicon precursor in the metal organic chemical vapor deposition equipment can be silane (SiH₄) or disilane (Si₂H₆). The n-type conductive layer 818 is sequentially fabricated by initially forming a gallium nitride layer doped with highly concentrated silicon or an aluminum gallium nitride doped with highly concentrated silicon, and then forming a gallium nitride layer doped with low concentrated silicon or an aluminum gallium nitride doped with low concentrated silicon. The gallium nitride layer doped with highly concentrated silicon or the aluminum gallium nitride doped with highly concentrated silicon can provide the n-type electrodes with better conductivity.

Thereafter, a luminescent layer 820 is formed on the n-type conductive layer 818, wherein the luminescent layer 820 can be a single hetero-structure, a double hetero-structure, a single quantum well layer, or a multiple quantum well layer. In the present invention, a multiple quantum well layer structure, namely a multiple quantum well layer/barrier layer structure, is adopted. The quantum well layer can be of indium gallium nitride, and the barrier layer can be made of a ternary alloy such as aluminum gallium nitride. Further, a quaternary alloy such as AlₓIn_{y}Ga_{l-x-y}N can be used for formation of the quantum well layer and the barrier layer, wherein the barrier layer with a wide band gap and the quantum well layer with a narrow band gap can be obtained by adjusting the concentrations of aluminum and indium in the aluminum indium gallium nitride. The luminescent layer 820 can be doped with n-type or p-type dopants, or can be doped with n-type and p-type dopants simultaneously, or can include no dopants. In addition, the quantum well layer can be doped and the barrier layer can be not doped; the quantum well layer can be not doped and the barrier layer can be doped; both the quantum well layer and the barrier layer can be doped; or neither the quantum well layer nor the barrier layer can be doped. Further, a portion of the quantum well layer can be delta-doped.

Next, an electron blocking layer 822 of p-type conduction is formed on the luminescent layer 820. The electron blocking layer 822 of p-type conduction may comprise a first Group III-V semiconductor layer and a second Group III-V semiconductor layer. The first and second Group III-V semiconductor layers can have two different band gaps, and are periodically and repeatedly deposited on the luminescent layer 820. The periodical and repeated deposition process can form an electron barrier layer having a wider band gap, which is higher than that of the active luminescent layer, so as to block excessive electrons overflowing from the luminescent layer 820. The first Group III-V semiconductor layer can be an aluminum indium gallium nitride (AlₓIn_{y}Ga_{l-x-y}N) layer. The second Group III-V semiconductor layer can be an aluminum indium gallium nitride (AlᵤInᵥGaₗ₋ᵤ₋ᵥN) layer, wherein 0≦x≦1, 0≦y≦1, x+y<1, 0≦u≦1, 0≦v≦1, and u+v<1. When x is equal to u, y is not equal to v. Further, the first and second Group III-V semiconductor layers can be of gallium nitride, aluminum nitride, indium nitride, aluminum gallium nitride, indium gallium nitride, or aluminum indium nitride.

Finally, a Group II atom is doped to form a p-type conductive layer 824 on the electron blocking layer 822. In the present embodiment, the Group II atom can be a magnesium atom. The magnesium precursor in the metal organic chemical vapor deposition equipment can be CP₂Mg. The p-type conductive layer 824 is sequentially fabricated by initially forming a gallium nitride layer doped with low concentrated magnesium or an aluminum gallium nitride doped with low concentrated magnesium, and then forming a gallium nitride layer doped with highly concentrated magnesium or an aluminum gallium nitride doped with highly concentrated magnesium. The gallium nitride layer doped with highly concentrated magnesium or the aluminum gallium nitride doped with highly concentrated magnesium can provide p-type electrodes with better conductivity.

As shown in FIG. 8D, a reflective metal layer 826 is formed on the semiconductor layer 816. The reflective metal layer 826 is configured to reflect light from the semiconductor layer 816 to a light-emitting surface so as to increase light output. The thin metal layer 826 can be formed on the semiconductor layer 816 using an evaporation process or a sputtering process. The reflective metal layer 826 may include silver or aluminum silver alloy.

Referring to FIG. 8E, an electrically conductive material layer 828 is formed on the reflective metal layer 826. The electrically conductive material layer 828 can be formed on the reflective metal layer 826 using an evaporation process or a sputtering process; or the electrically conductive material layer 828 can be bonded to the reflective metal layer 826. The electrically conductive material layer 828 can accelerate the dissipation of the heat from the semiconductor layer and improve the electrical conductivity. The electrically conductive material layer 828 may include diamond-like, copper, copper tungsten alloy or nickel.

Thereafter, two wet etching processes are performed to remove the temporary substrate 802. Referring to FIG. 8F, the silicon dioxide layer 804 is immersed in a properly selected and adjusted chemical solution. The chemical reaction between the silicon dioxide layer 804 and the chemical solution can be accelerated by applying ultrasonic energy, radiating UV light on the silicon dioxide layer 804, and increasing the temperature of the chemical solution. The temperature of the solution can be raised to about 150 degree Celsius. The chemical solution can be a buffer oxide etcher (BOE) solution, which is mainly used to etch silicon dioxide material or silicon nitride material. The BOE solution may be a mixture of aqueous ammonium fluoride (NH₄F) and aqueous hydrofluoric acid (HF). The chemical solution may be formulated by mixing 40 percent by weight aqueous ammonium fluoride with 49 percent by weight aqueous HF. The resulting chemical solution can be 10 percent volume BOE etchant. Specifically, 90 grams of transparent crystal solid ammonium fluoride is added to deionized water of 135 milliliters, and the deionized water is stirred to dissolve the ammonium fluoride. Using a volumetric flask, 180 milliliters of aqueous ammonium fluoride is prepared and poured into a container, and 20 milliliters of 49 percent by weight aqueous HF is added to the same container. After mixing, the BOE solution is obtained. When the chemical solution erodes the silicon dioxide layer, the cavities 814 between the Group III nitride buffer layer 812 and the silicon dioxide layer 804 increase the surface of the silicon dioxide layer 804 exposed to the chemical solution, facilitating the etching of the silicon dioxide layer in the chemical solution. Finally, after the silicon dioxide layer is removed, the Group III nitride buffer layer 812 including a plurality of pillar-like elements 830 and the temporary substrate 802 attached thereto is left.

The next step is related to the second etching process. Referring to FIG. 8G, another chemical solution enters the spaces 832 originally occupied by the silicon dioxide layer, etching the interface between the pillar-like elements 830 of the Group III nitride buffer layer 812 and the temporary substrate 802 to separate the temporary substrate 802. The chemical solution can be potassium hydroxide (KOH) solution, sulfuric acid solution (H₂SO₄), or phosphoric acid solution (H₃PO₄). The chemical reaction between the pillar-like elements 830 of the Group III nitride buffer layer is 812 and the chemical solution can be accelerated by applying ultrasonic energy, radiating UV light on the silicon dioxide layer 804, and increasing the temperature of the chemical solution. Finally, referring to FIGS. 8H and 81, as a result of the etching process that separates the temporary substrate 802 from the plurality of pillar-like elements 830 of the Group III nitride buffer layer 812, the surface of the Group III nitride buffer layer 812 becomes irregular, and the irregular surface may increase light output.

In summary, the present invention utilizes a wet etching process to remove a temporary substrate so that the laser lift off technique is not required and the damage to the semiconductor layer due to the usage of the laser lift off technique can be avoided. Further, utilizing a wet etching process can make the processing steps simpler, resulting in lower manufacturing cost. In a vertical light-emitting device, the wet etching process can generate irregular surfaces that can increase the light output of the device. In addition, the adoption of the wet etching process in the manufacturing process may increase the amount of processed products per batch, further reducing the manufacturing cost.

The above-described embodiments of the present invention are intended to be illustrative only. Numerous alternative embodiments may be devised by persons skilled in the art without departing from the scope of the following claims.

What is claimed is:

1. A method for separating a substrate from a semiconductor layer, comprising the steps of:
providing a temporary substrate;
forming a patterned silicon dioxide layer on said temporary substrate;
forming a semiconductor layer on said patterned silicon dioxide layer;
performing a first etching process upon said patterned silicon dioxide layer; and
performing a second etching process upon an interface between said temporary substrate and said semiconductor layer to remove said temporary substrate.

2. The method of claim 1, wherein said first etching process is a wet etching process.

3. The method of claim 1, wherein said second etching process is is a wet etching process.

4. The method of claim 1, further comprising a step of forming a reflective metal layer on said semiconductor layer.

5. The method of claim 4, further comprising a step of forming an electrically conductive material layer on said reflective metal layer.

6. The method of claim 1, wherein said semiconductor layer comprises an n-type conductive layer, a luminescent layer, and a p-type conductive layer.

7. The method of claim 6, wherein said semiconductor layer further comprises an electron blocking layer disposed between said luminescent layer and said p-type conductive layer.

8. The method of claim 1, wherein said patterned silicon dioxide layer is a continuous layer or a partially continuous layer.

9. The method of claim 1, wherein said patterned silicon dioxide layer has a thickness in a range of from 0.05 to 2 micrometers.

10. The method of claim 1, wherein said patterned silicon dioxide layer includes a width in a range of from 0.1 to 10 micrometers.

11. A method for separating a substrate from a semiconductor layer, comprising the steps of:
providing a temporary substrate;
forming a patterned silicon dioxide layer including a plurality of cavities on said temporary substrate;
forming a cavity filling layer on said patterned silicon dioxide layer;
forming a semiconductor layer on said cavity filling layer;
performing a first etching process upon said patterned silicon dioxide layer; and
performing a second etching process upon said cavity filling layer to remove said temporary substrate.

12. The method of claim 11, wherein said first etching process is a wet etching process.

13. The method of claim 11, wherein said second etching process is a wet etching process.

14. The method of claim 11, further comprising a step of forming a reflective metal layer on said semiconductor layer.

15. The method of claim 14, further comprising a step of forming an electrically conductive material layer on said reflective metal layer.

16. The method of claim 11, wherein said semiconductor layer comprises an n-type conductive layer, a luminescent layer, and a p-type conductive layer.

17. The method of claim 16, wherein said semiconductor layer further comprises an electron blocking layer disposed between said luminescent layer and said p-type conductive layer.

18. The method of claim 11, wherein said patterned silicon dioxide layer includes a continuous layer or a partially continuous layer.

19. The method of claim 11, wherein said patterned silicon dioxide layer has a thickness in a range of from 0.05 to 2 micrometers.

20. The method of claim 19, wherein said patterned silicon dioxide layer includes a width in a range of from 0.1 to 10 micrometers.
